(19) United States
(12) Patent Application Publication
(10) Pub. No.: US 2025/0118381 A1
(43) Pub. Date: Apr. 10, 2025

(54) NONVOLATILE MEMORY DEVICE AND PASS-FAIL CHECK METHOD THEREOF

(71) Applicant: SAMSUNG ELECTRONICS CO., LTD., Suwon-si (KR)

(72) Inventors: Jungmin Park, Suwon-si (KR); Sion Kim, Suwon-si (KR); Joonsuc Jang, Suwon-si (KR)

(21) Appl. No.: 18/899,546

(22) Filed: Sep. 27, 2024

(30) Foreign Application Priority Data
Oct. 5, 2023 (KR) 10-2023-0132509

(51) Int. Cl. G11C 16/34; G11C 16/08; G11C 16/10

(52) U.S. Cl. CPC G11C 16/3459; G11C 16/08; G11C 16/102

(57) ABSTRACT

An example operating method of a nonvolatile memory device includes applying a first verification voltage to selected memory cells in a first program loop that verifies pass or fail of a first program state among a plurality of program states, applying a second verification voltage to the selected memory cells in the first program loop that verifies pass or fail of a second program state among the plurality of program states, applying a program voltage to the selected memory cells in a second program loop, and verifying, based on the program voltage being applied to the selected memory cells, pass or fail of the first program state and the second program state for the selected memory cells based on a result of applying the first verification voltage and a result of applying the second verification voltage.

### CROSS-REFERENCE TO RELATED APPLICATION

This application claims priority under 35 USC § 119 to Korean Patent Application No. 10-2023-0132509, filed on Oct. 5, 2023, in the Korean Intellectual Property Office, the disclosure of which is incorporated by reference herein in its entirety.

### BACKGROUND

Semiconductor memory devices are implemented using semiconductors, such as silicon (Si), germanium (Ge), gallium arsenide (GaAs), and indium phosphide (InP). Semiconductor memory devices may be broadly divided into volatile memory devices and nonvolatile memory devices.

In particular, nonvolatile memory devices, such as flash memory devices have been used in various fields due to their advantages, such as fast operation speed, low power, low noise, and high capacity. A nonvolatile memory device may count off-cells (or on-cells) among memory cells using a certain verification voltage to recognize a program state of the memory cells. The nonvolatile memory device may recognize a threshold voltage distribution pattern of the memory cells and characteristics of the memory cells through the number of counted off-cells and perform memory operations, such as a program operation or a read operation based on the recognized threshold voltage distribution form of the memory cells and the characteristics of the memory cells.

In addition, in certain memory operations, it is necessary to accurately recognize the threshold voltage distribution pattern of the memory cells and the characteristics of the memory cells, and thus, to this end, research on a nonvolatile memory device that may rapidly and accurately count the number of off-cells has been conducted.

### SUMMARY

The present disclosure relates to memory devices and methods, including a method of improving program distortion and shortening program time in a nonvolatile memory device.

In general, according to some aspects, an operating method of a nonvolatile memory device includes applying a first verification voltage for verifying pass or fail of a first program state among a plurality of program states, to selected memory cells in a first program loop, applying a second verification voltage for verifying pass or fail of a second program state among the plurality of program states, to the selected memory cells in the first program loop, applying a program voltage to the selected memory cells in a second program loop, and verifying pass or fail of the first program state and the second program state for the selected memory cells based on a result of the applying of the first verification voltage and a result of the applying of the second verification voltage, while the program voltage is applied to the selected memory cells.

In general, according to some aspects, a nonvolatile memory device includes a memory cell array including a plurality of memory cells, a page buffer circuit including a plurality of page buffer blocks connected to the memory cell array through bit lines, a control logic configured to apply a first verification voltage for verifying pass or fail of a first program state, among a plurality of program states, to selected memory cells among the plurality of memory cells in a first program loop, apply a second verification voltage for verifying pass or fail of a second program state, among the plurality of program state, to the selected memory cells in the first program loop, and apply a program voltage to the selected memory cells in a second program loop, and a mass bit counter configured to verify pass or fail of the first program state and the second program state for the selected memory cells based on a result of applying the first verification voltage and a result of applying the second verification voltage, while the program voltage is applied to the selected memory cells.

In general, according to some aspects, an operating method of a nonvolatile memory device includes applying a program voltage to selected memory cells, applying a first verification voltage for verifying pass or fail of a first program state among a plurality of program states, to the selected memory cells, applying a second verification voltage for verifying pass or fail of a second program state among the plurality of program states, to the selected memory cells, and verifying pass or fail of the first program state and the second program state for the selected memory cells, based on a result of the applying of the first verification voltage and a result of the applying of the second verification voltage, after applying the first verification voltage and the second verification voltage to the memory cells.

### BRIEF DESCRIPTION OF THE DRAWINGS

Implementations will be more clearly understood from the following detailed description taken in conjunction with the accompanying drawings.

FIG. 1 is a block diagram illustrating an example of a memory system.

FIG. 2 is a block diagram illustrating an example of an implementation of a memory device in the memory system of FIG. 1.

FIGS. 3A to 3C are example diagrams illustrating a three-dimensional (3D) V-NAND structure that may be applied to a memory device of FIG. 1.

FIG. 4 is a diagram illustrating an example of a program operation for memory cells.

FIG. 5 illustrates an example of a timing of a pass-fail check operation in a program state.

FIGS. 6A, 6B, 6C, 6D, and 6E illustrate a sequential operation of an example of a nonvolatile memory device.

FIGS. 7A and 7B illustrate a sequential operation of an example of a nonvolatile memory device.

FIG. 8 illustrates an example of a timing of a pass-fail check operation of a program state.

FIG. 9 illustrates an example of a timing of a pass-fail check operation of a program state.

FIG. 10 illustrates an example of a method of operating a memory device.

FIG. 11 illustrates an example of a timing of a pass-fail check operation of a program state.

FIG. 12 is a block diagram illustrating an example of a solid state drive (SSD).

### DETAILED DESCRIPTION

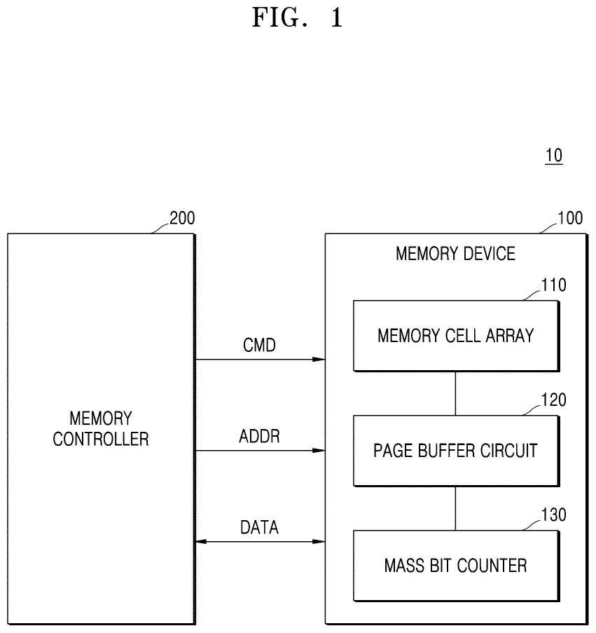

FIG. 1 is a block diagram illustrating an example of a memory system 10.

Referring to FIG. 1, the memory system 10 may include a memory controller 200 and a memory device 100. In some implementations, the memory system 10 may be implemented as one chip, one semiconductor package, or one module. In some implementations, the memory controller 200 and the memory device 300 may each be implemented as one chip, one semiconductor package, or one module. The memory system 10 may be used as a storage medium for an external device (e.g., a host, application processor, etc.). The memory system 10 may be a high-capacity storage medium, such as a memory card, memory stick, or solid state drive (SSD).

The memory controller 200 may control the memory device 100 according to the control by an external device. The memory controller 200 may transmit an address ADDR and a command CMD to the memory device 100 or transmit or receive data DATA to or from the memory device 100.

The memory device 100 may include a memory cell array 110, a page buffer circuit 120, and a mass bit counter 130. The memory cell array 110 may include a plurality of memory cells. In some implementations, the memory cell array 110 may be a NAND flash memory cell array or a NOR flash memory cell array. Hereinafter, implementations are described in detail on the assumption that the memory cells are NAND flash memory cells. However, the present disclosure is not limited thereto, and in some implementations, the memory cells may include resistive memory cells, such as resistive random access memory (RRAM), phase change RAM (PRAM), or magnetic RAM (MRAM) or may include a volatile memory cell, such as a dynamic RAM.

The page buffer circuit 120 may include a plurality of page buffer blocks connected to the memory cell array 110 through a plurality of bit lines. After a program operation is performed on the memory cells of the memory cell array 110, a certain verification voltage (or a read voltage) may be applied to word lines of the memory cells.

The memory system 10 according to some implementations may operate using a pass-fail check method described below, and a program operation time may be reduced by reducing the number of program loops.

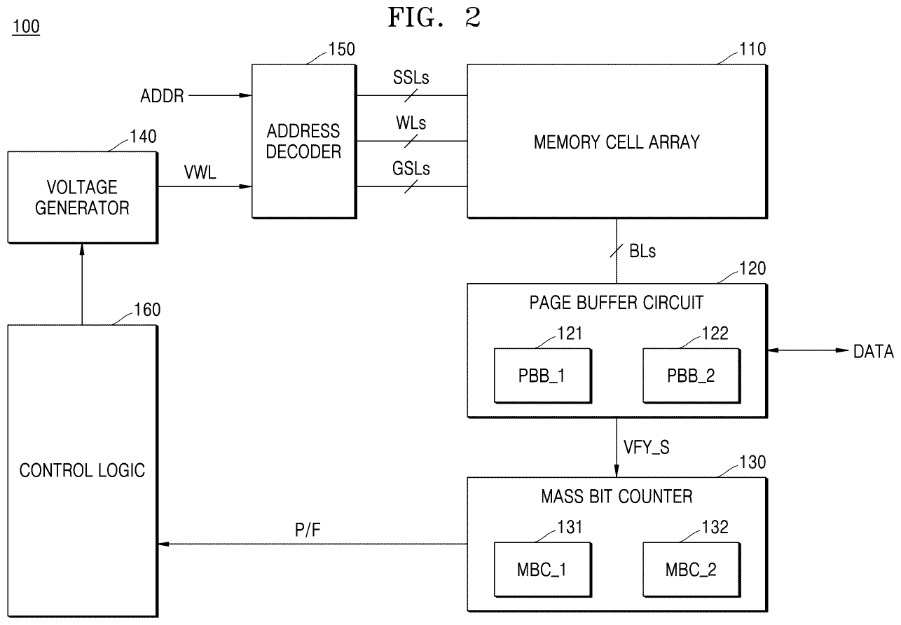

FIG. 2 is a block diagram illustrating an example of an implementation of the memory device 100 of the memory system of FIG. 1.

Referring to FIG. 2, the memory device 100 may include the memory cell array 110, the page buffer circuit 120, the mass bit counter 130, a voltage generator 140, an address decoder 150, and a control logic 160. The page buffer circuit 120 may include a first page buffer block (PBB_1) 121 and a second page buffer block (PBB_2) 122. The mass bit counter 130 may include a first mass bit counter (MBC_1) 131 and a second mass bit counter (MBC_2) 132. Meanwhile, unlike FIG. 2, the control logic 160 may include the mass bit counter 130.

The memory cell array 110 may be connected to the address decoder 150 through wordlines WLs, string select lines SSLs, and ground select lines GSLs and may be connected to the page buffer circuit 120 through bitlines BLs. The memory cell array 110 may include a plurality of memory blocks. The memory cell array 110 may include a plurality of NAND cell strings. Each cell string may form a channel in a vertical or horizontal direction. The word lines WLs may be stacked in the vertical direction in the memory cell array 110. The memory blocks include a plurality of memory cells.

The address decoder 150 may decode the address ADDR and select one of the word lines WLs of the memory cell array 110. The address decoder 150 may apply a program voltage provided from the voltage generator 140 to the selected word line of the memory cell array 110 during a program operation. In addition, the address decoder 150 may apply a verification voltage or read voltage provided from the voltage generator 140 to the selected word line of the memory cell array 110 during a verify operation or read operation. The voltage generator 140 may generate a plurality of program loops using a plurality of program voltages and a plurality of verification voltages as one program loop.

A data input/output (I/O) circuit may be connected to the page buffer circuit 120 through data lines DLs and may provide input data DQ to the page buffer circuit 120 or output data DATA provided from the page buffer circuit 120 externally. The data I/O circuit may provide an input command or address to the control logic 160 or the address decoder 150.

The page buffer circuit 120 may operate as a program driver or a sense amplifier depending on an operation performed by the control logic 160. During a program operation, the page buffer circuit 120 may provide a voltage corresponding to data to be programmed to the bit lines BLs of the memory cell array 110. During a verify operation or a read operation, the page buffer circuit 120 may sense data programmed in a selected memory cell through the bit lines BLs and provide the data to the control logic 160 or the data I/O circuit. The page buffer circuit 120 may receive at least one output based on the verification voltage from the memory cell array 110 through at least one bit line. The page buffer circuit 120 may transmit a signal generated from the at least one received output to the mass bit counter 130. For example, the page buffer circuit 120 may transmit a verification signal VFY_S to the mass bit counter 130. The mass bit counter 130 may count fail bits based on the verification signal VFY_S.

The control logic 160 may perform verification on a program operation performed on the memory cell array 110 using the page buffer circuit 120. The mass bit counter 130 may count the number of on-cells using verification signals VFY_S.

In the present disclosure, the mass bit counter 130 is generally described as counting the number of on-cells, but this is for convenience of description, and without being limited thereto, the mass bit counter may count the number of off-cells and perform a memory operation based thereon. In addition, it is clear that the present disclosure may be applied to implementations in which the number of off-cells or the number of on-cells is counted.

According to some implementations, the memory device 100 may include the memory cell array 110 including memory cells, the page buffer circuit 120 including a plurality of page buffers connected to the memory cell array through bit lines, the control logic 160, and the mass bit counter 130.

The control logic 160 according to some implementations may apply a first verification voltage for verifying pass or fail of a first program state among a plurality of program states, to selected memory cells among the memory cells in a first program loop. The control logic 160 may apply a second verification voltage for verifying pass or fail of a second program state among the program states, to the selected memory cells in the first program loop. The control logic 160 may apply a program voltage to the selected memory cells in a second program loop.

While the control logic 160 is applying the program voltage to the selected memory cells, the mass bit counter 130 according to some implementations may verify pass or fail of the first program state and the second program state for the selected memory cells, based on a result of applying the first verification voltage and a result of applying the second verification voltage. Applying the first verification voltage may be based on a multiple-step verification method including a 2-step verify method, and applying the second verification voltage may be based on a 1-step verification method. For example, the first verification voltage may include three verification voltages, and the selected memory cells may be programmed by an incremental step pulse programming (ISPP) scheme using a 3-step verification method, while the second verification voltage may include one verification voltage. That is, the first verification for the first program state and the second verification for the second program state may be based on verification methods having different steps.

As an example, the mass bit counter 130 may count the number of first fail bits as the result of applying the first verification voltage and the number of second fail bits as the result of applying the second verification voltage. In addition, the mass bit counter 130 may calculate the number of third fail bits by adding the number of first fail bits and the number of second fail bits. The mass bit counter 130 may determine whether the first program state and the second program state are pass based on the number of third fail bits.

For example, the mass bit counter 130 may compare the number of third fail bits with the number of fourth reference bits. In addition, when the number of third fail bits is less than the number of fourth reference bits, the mass bit counter 130 may determine that both the first program state and the second program state are pass. If the number of third fail bits is less than the number of fourth reference bits, the mass bit counter 130 may determine that both the first program state and the second program state are pass. The fourth reference bit refers to a value less than the number of third reference bits obtained by adding the number of first reference bits for the first program state to the number of second reference bits for the second program state. When the number of third fail bits is greater than or equal to the number of fourth reference bits, the mass bit counter 130 may determine that both the first program state and the second program state are fail.

For example, the mass bit counter 130 may include a first mass bit counter (MBC_1) 131 and a second mass bit counter (MBC_2) 132. The page buffer blocks may include the first page buffer block 121 and the second page buffer block 122. The first mass bit counter 131 connected to the first page buffer block 121 may count the number of first fail bits according to the result of applying the first verification voltage and compare the number of first fail bits with the number of first reference bits for the first program state, and if the number of first fail bits is less than the number of first reference bits, the first mass bit counter 131 may determine that the first program state is pass. The second mass bit counter 132 connected to the second page buffer block 122 may count the number of second fail bits according to the result of applying the second verification voltage. The second mass bit counter 132 may compare the number of second fail bits with the number of second reference bits for the second program state. The second mass bit counter 132 may determine that the second program state is pass when the number of second fail bits is less than the number of second reference bits.

When the selected memory cell is a quadruple level cell (QLC), the program states include an erase state and 15 program states. The first program state and the second program state may be adjacent to each other among 15 program states. For example, the second program state may be a highest program state with a highest target threshold voltage, and the first program state may be a second-highest program state with a second-highest target threshold voltage. That is, when a distribution of target threshold voltages of 15 plural program states {P1, P2, . . . , P15} is sorted in ascending order, the highest state may be P15 and the second-highest state may be P14. The first program state P14 and the second program state P15 may be verified based on different program methods. For example, the first program state P14 may be verified using a 2-step verification method, and the second program state P15 may be verified using a 1-step verification method. Accordingly, the memory device 100 may perform a pass-fail check in the same program loop for program states with different verification methods. That is, for convenience of description, the pass-fail check for two program states has been described, but the aforementioned method may be applied to a case of performing a pass-fail check for multiple program states simultaneously and is not limited to the implementation described above. As an example, the memory device 100 may verify the program states P13, P14, and P15 together.

When the selected memory cell is a triple level cell (TLC), the program states include an erase state and seven program states. The first program state and the second program state may be adjacent to each other among the seven program states. For example, the second program state may be the highest program state with the highest target threshold voltage, and the first program state may be the second-highest program state with the second-highest target threshold voltage. That is, when the distribution of target threshold voltages of seven plural program states {P1, P2, . . . , P7} is sorted in ascending order, the highest state may be P7 and the second-highest state may be P6. The first program state P14 and the second program state P15 may be verified based on different program methods. For example, the first program state P6 may be verified using a 2-step verification method, and the second program state P7 may be verified using a 1-step verification method. Accordingly, the memory device 100 may perform a pass-fail check in the same program loop for program states with different verification methods. When the first program state and the second program state have different verification methods and are consecutive to each other, the pass-fail check method according to the present disclosure may be used, and the present disclosure is not limited to an implementation in which the first program state is the second-highest program state and the second program state is the highest program state. That is, for convenience of description, the pass-fail check for two program states has been described, but the aforementioned method may be applied to a case of performing a pass-fail check for multiple program states simultaneously and is not limited to the implementation described above. As an example, the memory device 100 may verify the program states P5, P6, and P7 together.

The memory device 100 according to some implementations may reduce the total number of program loops by performing a pass-fail check on the second-highest program state and the highest program state during one program loop. Accordingly, the memory device 100 according to some implementations may reduce time required for a program operation. A nonvolatile memory device according to some implementations may reduce program distortion. In the case of TLC and QLC, a gap between program states is narrow, so the second-highest program state and the highest program state, which are slow in a program speed due to bitline forcing, may be passed at the same time.

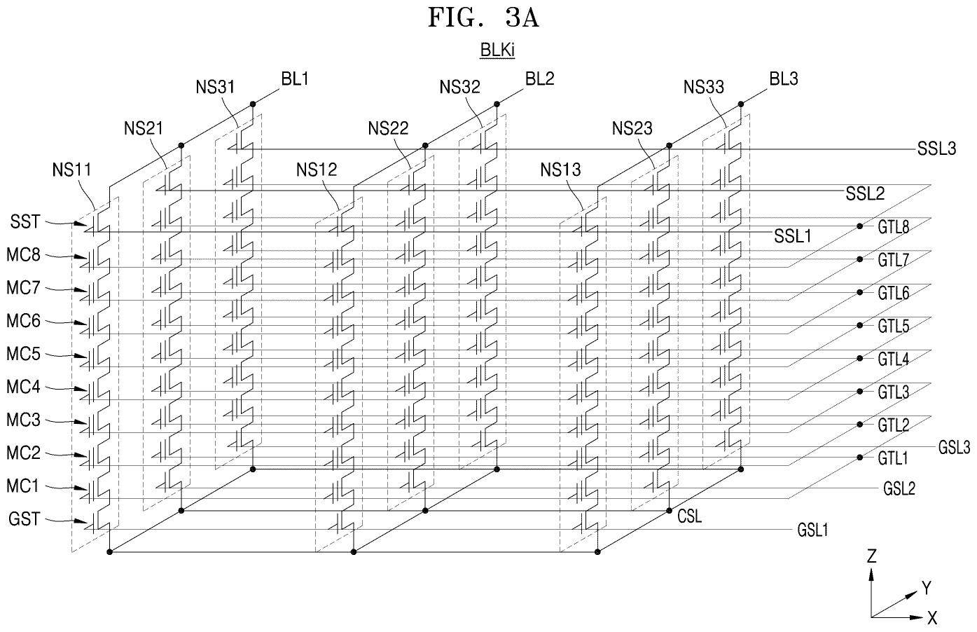

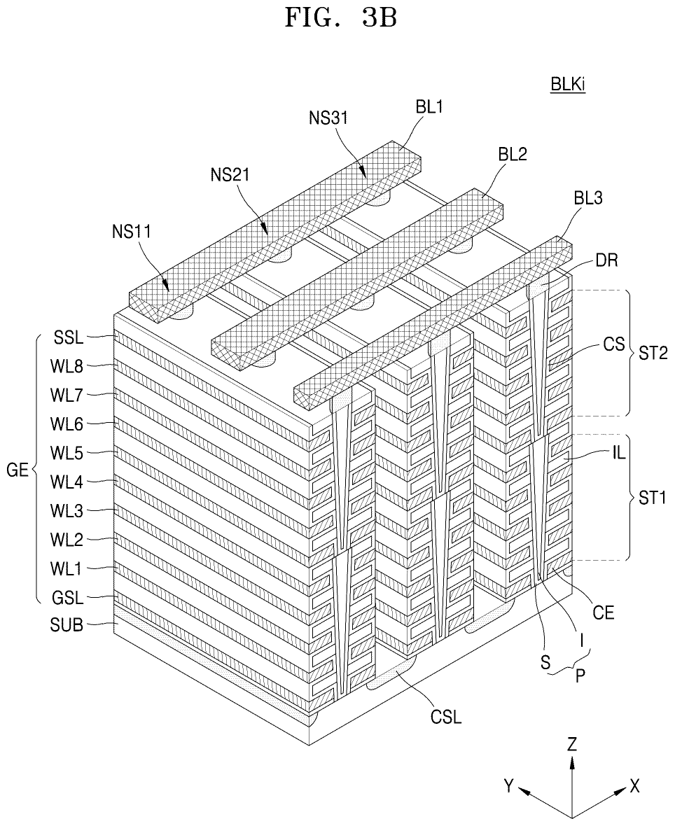

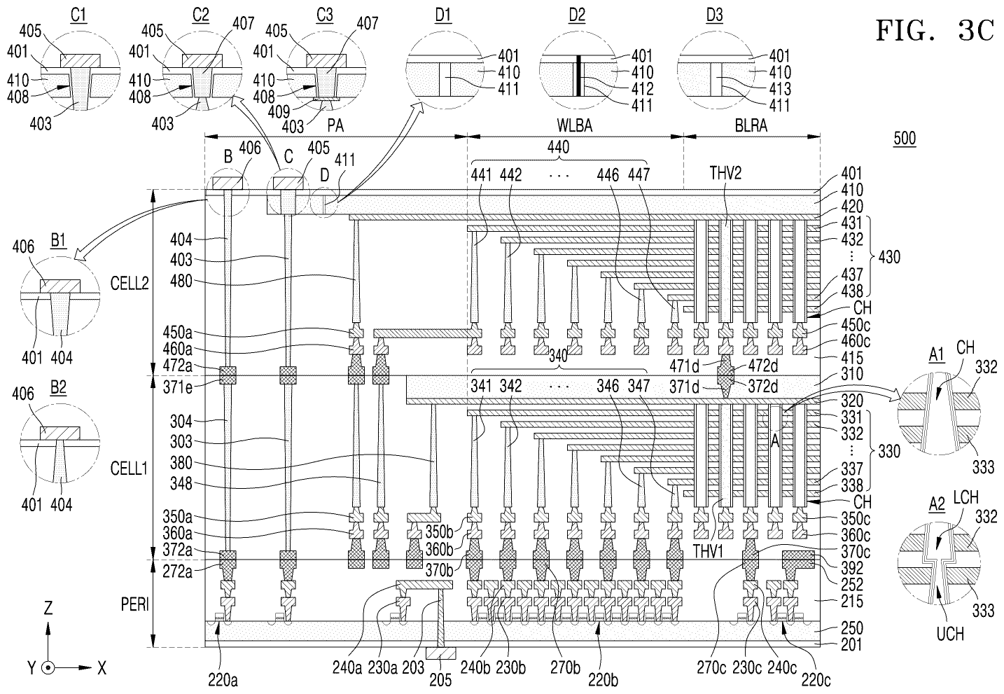

FIGS. 3A to 3C are example diagrams illustrating a three-dimensional (3D) V-NAND structure that may be applied to the memory device 100 of FIG. 1.

The memory cell array 110 (FIG. 1) of the memory device 100 (FIG. 1) may include a plurality of memory blocks. FIGS. 3A and 3B illustrate a structure of one memory block BLKi among the memory blocks, and FIG. 3C illustrates an implementation example of a structure of the memory device 100 of FIG. 1.

Referring to FIG. 3A, the memory block BLKi may include a plurality of memory NAND strings NS11 to NS33 connected between bit lines BL1, BL2, and BL3 and a common source line CSL. Each of the memory NAND strings NS11 to NS33 may include a string select transistor SST, a plurality of memory cells MC1 to MC8, and a ground select transistor GST. For brevity of the drawing, FIG. 3A illustrates that each of the memory NAND strings NS11 to NS33 includes eight memory cells MC1 to MC8, but is not limited thereto.

The string select transistor SST may be connected to the corresponding string select line SSL1, SSL2, and SSL3. The memory cells MC1 to MC8 may be connected to corresponding gate lines GTL1 to GTL8, respectively. The gate lines GTL1 to GTL8 may correspond to word lines, and some of the gate lines GTL1 to GTL8 may correspond to dummy word lines. The ground select transistor GST may be connected to the corresponding ground select line GSL1, GSL2, and GSL3. The string select transistor SST may be connected to the corresponding bit lines BL1, BL2, and BL3, and the ground select transistor GST may be connected to the common source line CSL.

The gate lines (e.g., GTL1) of the same height may be connected in common, and the ground select lines GSL1, GSL2, and GSL3 and the string select lines SSL1, SSL2, and SSL3 may be separated from each other. In FIG. 3A, the memory block BLKi is shown as being connected to eight gate lines GTL1 to GTL8 and three bit lines BL1, BL2, and BL3 but is not limited thereto. Referring further to FIG. 3B, the memory block BLKi is formed in a vertical direction with respect to a substrate SUB. Memory cells constituting the memory NAND strings NS11 to NS33 are stacked on a plurality of semiconductor layers to be formed.

On the substrate SUB, the common source line CSL extending in a first direction (a Y direction) is provided. On a region of the substrate SUB between two adjacent common source lines CSL, a plurality of insulating films IL extending in the first direction (the Y direction) are sequentially provided in a third direction (a Z direction) and may be apart from each other in the third direction (the Z direction). On a region of the substrate SUB between two adjacent common source lines CSL, a plurality of pillars P are sequentially arranged in the first direction (the Y direction) and pass through the plurality of insulating films IL in the third direction (the Z direction). The pillars P may contact the substrate SUB through the insulating films IL. A surface layer S of each pillar P may include a silicon material doped with a first conductivity type and may function as a channel region.

An internal layer I of each pillar P may include an insulating material, such as silicon oxide, or an air gap. In a region between two adjacent common source lines CSL, a charge storage layer CS is provided along the exposed surfaces of the insulating films IL, pillars P, and substrate SUB. The charge storage layer CS may include a gate insulating layer (also referred to as a ‘tunneling insulating layer’), a charge trap layer, and a blocking insulating layer. In addition, in a region between two adjacent common source lines CSL, gate electrodes GE, such as select lines GSL and SSL and word lines WL1 to WL8, are formed on the exposed surface of the charge storage layer CS. Drains or drain contacts DR may be provided on the pillars P, respectively. On the drain contacts DR, bit lines BL1 to BL3 may extend in a second direction (an X direction) and are apart by a certain distance in the first direction (the Y direction).

As shown in FIG. 3B, each of the memory NAND strings NS11 to NS33 may be implemented as a structure in which a first memory stack ST1 and a second memory stack ST2 are stacked. The first memory stack ST1 is connected to the common source line CSL, the second memory stack ST2 is connected to the bit lines BL1 to BL3, and the first memory stack ST1 may be stacked on the second memory stack ST2 to share channel holes with each other.

FIG. 3C is a view illustrating an example of a memory device 500.

Referring to FIG. 3C, the memory device 500 may have a chip-to-chip (C2C) structure. At least one upper chip including a cell region and a lower chip including a peripheral circuit region PERI may be manufactured separately, and then, the at least one upper chip and the lower chip may be connected to each other by a bonding method to realize the C2C structure. For example, the bonding method may mean a method of electrically or physically connecting a bonding metal pattern formed in an uppermost metal layer of the upper chip to a bonding metal pattern formed in an uppermost metal layer of the lower chip. For example, in a case in which the bonding metal patterns are formed of copper (Cu), the bonding method may be a Cu—Cu bonding method. Alternatively, the bonding metal patterns may be formed of aluminum (Al) or tungsten (W).

The memory device 500 may include the at least one upper chip including the cell region. For example, as illustrated in FIG. 3c, the memory device 500 may include two upper chips. However, the number of the upper chips is not limited thereto. In the case in which the memory device 500 may include the two upper chips, a first upper chip including a first cell region CELL1, a second upper chip including a second cell region CELL2 and the lower chip including the peripheral circuit region PERI may be manufactured separately, and then, the first upper chip, the second upper chip and the lower chip may be connected to each other by the bonding method to manufacture the memory device 500. The first upper chip may be turned over and then may be connected to the lower chip by the bonding method, and the second upper chip may also be turned over and then may be connected to the first upper chip by the bonding method. Hereinafter, the upper and lower portions of each of the first and second upper chips will be defined based on before each of the first and second upper chips is turned over. In other words, an upper portion of the lower chip may mean an upper portion defined based on a +Z-axis direction, and the upper portion of each of the first and second upper chips may mean an upper portion defined based on a −Z-axis direction in FIG. 3c. However, implementations are not limited thereto. In some implementations, one of the first upper chip and the second upper chip may be turned over and then may be connected to a corresponding chip by the bonding method.

Each of the peripheral circuit region PERI and the first and second cell regions CELL1 and CELL2 of the memory device 500 may include an external pad bonding region PA, a word line bonding region WLBA, and a bit line bonding region BLBA.

The peripheral circuit region PERI may include a first substrate 210 and a plurality of circuit elements 220a, 220b and 220c formed on the first substrate 210. An interlayer insulating layer 215 including one or more insulating layers may be provided on the circuit elements 220a, 220b and 220c, and a plurality of metal lines electrically connected to the circuit elements 220a, 220b and 220c may be provided in the interlayer insulating layer 215. For example, the metal lines may include first metal lines 230a, 230b and 230c connected to the circuit elements 220a, 220b and 220c, and second metal lines 240a, 240b and 240c formed on the first metal lines 230a, 230b and 230c. The metal lines may be formed of at least one of various conductive materials. For example, the first metal lines 230a, 230b and 230c may be formed of tungsten having a relatively high electrical resistivity, and the second metal lines 240a, 240b and 240c may be formed of copper having a relatively low electrical resistivity.

The first metal lines 230a, 230b and 230c and the second metal lines 240a, 240b and 240c are illustrated and described in the present implementations. However, implementations are not limited thereto. In some implementations, at least one or more additional metal lines may further be formed on the second metal lines 240a, 240b and 240c. In this case, the second metal lines 240a, 240b and 240c may be formed of aluminum, and at least some of the additional metal lines formed on the second metal lines 240a, 240b and 240c may be formed of copper having an electrical resistivity lower than that of aluminum of the second metal lines 240a, 240b and 240c.

The interlayer insulating layer 215 may be disposed on the first substrate 210 and may include an insulating material, such as silicon oxide and/or silicon nitride.

Each of the first and second cell regions CELL1 and CELL2 may include at least one memory block. The first cell region CELL1 may include a second substrate 310 and a common source line 320. A plurality of word lines 330 (331 to 338) may be stacked on the second substrate 310 in a direction (i.e., the Z-axis direction) perpendicular to a top surface of the second substrate 310. String select lines and a ground select line may be disposed on and under the word lines 330, and the word lines 330 may be disposed between the string select lines and the ground select line. Likewise, the second cell region CELL2 may include a third substrate 410 and a common source line 420, and a plurality of word lines 430 (431 to 438) may be stacked on the third substrate 410 in a direction (i.e., the Z-axis direction) perpendicular to a top surface of the third substrate 410. Each of the second substrate 310 and the third substrate 410 may be formed of at least one of various materials and may be, for example, a silicon substrate, a silicon-germanium substrate, a germanium substrate, or a substrate having a single-crystalline epitaxial layer grown on a single-crystalline silicon substrate. A plurality of channel structures CH may be formed in each of the first and second cell regions CELL1 and CELL2.

In some implementations, as illustrated in a region ‘A1’, the channel structure CH may be provided in the bit line bonding region BLBA and may extend in the direction perpendicular to the top surface of the second substrate 310 to penetrate the word lines 330, the string select lines, and the ground select line. The channel structure CH may include a data storage layer, a channel layer, and a filling insulation layer. The channel layer may be electrically connected to a first metal line 350c and a second metal line 360c in the bit line bonding region BLBA. For example, the second metal line 360c may be a bit line and may be connected to the channel structure CH through the first metal line 350c. The bit line 360c may extend in a first direction (e.g., a Y-axis direction) parallel to the top surface of the second substrate 310.

In some implementations, as illustrated in a region ‘A2’, the channel structure CH may include a lower channel LCH and an upper channel UCH, which are connected to each other. For example, the channel structure CH may be formed by a process of forming the lower channel LCH and a process of forming the upper channel UCH. The lower channel LCH may extend in the direction perpendicular to the top surface of the second substrate 310 to penetrate the common source line 320 and lower word lines 331 and 332. The lower channel LCH may include a data storage layer, a channel layer, and a filling insulation layer and may be connected to the upper channel UCH. The upper channel UCH may penetrate upper word lines 333 to 338. The upper channel UCH may include a data storage layer, a channel layer, and a filling insulation layer, and the channel layer of the upper channel UCH may be electrically connected to the first metal line 350c and the second metal line 360c. As a length of a channel increases, due to characteristics of manufacturing processes, it may be difficult to form a channel having a substantially uniform width. The memory device 500 according to the present implementations may include a channel having improved width uniformity due to the lower channel LCH and the upper channel UCH which are formed by the processes performed sequentially.

In the case in which the channel structure CH may include the lower channel LCH and the upper channel UCH as illustrated in the region ‘A2’, a word line located near to a boundary between the lower channel LCH and the upper channel UCH may be a dummy word line. For example, the word lines 332 and 333 adjacent to the boundary between the lower channel LCH and the upper channel UCH may be the dummy word lines. In this case, data may not be stored in memory cells connected to the dummy word line. Alternatively, the number of pages corresponding to the memory cells connected to the dummy word line may be less than the number of pages corresponding to the memory cells connected to a general word line. A level of a voltage applied to the dummy word line may be different from a level of a voltage applied to the general word line, and thus it is possible to reduce an influence of a non-uniform channel width between the lower and upper channels LCH and UCH on an operation of the memory device.

Meanwhile, the number of the lower word lines 331 and 332 penetrated by the lower channel LCH is less than the number of the upper word lines 333 to 338 penetrated by the upper channel UCH in the region ‘A2’. However, implementations are not limited thereto. In some implementations, the number of the lower word lines penetrated by the lower channel LCH may be equal to or more than the number of the upper word lines penetrated by the upper channel UCH. In addition, structural features and connection relations of the channel structure CH disposed in the second cell region CELL2 may be substantially the same as those of the channel structure CH disposed in the first cell region CELL1.

In the bit line bonding region BLBA, a first through-electrode THV1 may be provided in the first cell region CELL1, and a second through-electrode THV2 may be provided in the second cell region CELL2. As illustrated in FIG. 3c, the first through-electrode THV1 may penetrate the common source line 320 and the word lines 330. In some implementations, the first through-electrode THV1 may further penetrate the second substrate 310. The first through-electrode THV1 may include a conductive material. Alternatively, the first through-electrode THV1 may include a conductive material surrounded by an insulating material. The second through-electrode THV2 may have the same shape and structure as the first through-electrode THV1.

In some implementations, the first through-electrode THV1 and the second through-electrode THV2 may be electrically connected to each other through a first through-metal pattern 372d and a second through-metal pattern 472d. The first through-metal pattern 372d may be formed at a bottom end of the first upper chip including the first cell region CELL1, and the second through-metal pattern 472d may be formed at a top end of the second upper chip including the second cell region CELL2. The first through-electrode THV1 may be electrically connected to the first metal line 350c and the second metal line 360c. A lower via 371d may be formed between the first through-electrode THV1 and the first through-metal pattern 372d, and an upper via 471d may be formed between the second through-electrode THV2 and the second through-metal pattern 472d. The first through-metal pattern 372d and the second through-metal pattern 472d may be connected to each other by the bonding method.

In addition, in the bit line bonding region BLBA, an upper metal pattern 252 may be formed in an uppermost metal layer of the peripheral circuit region PERI, and an upper metal pattern 392 having the same shape as the upper metal pattern 252 may be formed in an uppermost metal layer of the first cell region CELL1. The upper metal pattern 392 of the first cell region CELL1 and the upper metal pattern 252 of the peripheral circuit region PERI may be electrically connected to each other by the bonding method. In the bit line bonding region BLBA, the bit line 360c may be electrically connected to a page buffer included in the peripheral circuit region PERI. For example, some of the circuit elements 220c of the peripheral circuit region PERI may constitute the page buffer, and the bit line 360c may be electrically connected to the circuit elements 220c constituting the page buffer through an upper bonding metal pattern 370c of the first cell region CELL1 and an upper bonding metal pattern 270c of the peripheral circuit region PERI.

Referring continuously to FIG. 3c, in the word line bonding region WLBA, the word lines 330 of the first cell region CELL1 may extend in a second direction (e.g., an X-axis direction) parallel to the top surface of the second substrate 310 and may be connected to a plurality of cell contact plugs 340 (341 to 347). First metal lines 350b and second metal lines 360b may be sequentially connected onto the cell contact plugs 340 connected to the word lines 330. In the word line bonding region WLBA, the cell contact plugs 340 may be connected to the peripheral circuit region PERI through upper bonding metal patterns 370b of the first cell region CELL1 and upper bonding metal patterns 270b of the peripheral circuit region PERI.

The cell contact plugs 340 may be electrically connected to a row decoder included in the peripheral circuit region PERI. For example, some of the circuit elements 220b of the peripheral circuit region PERI may constitute the row decoder, and the cell contact plugs 340 may be electrically connected to the circuit elements 220b constituting the row decoder through the upper bonding metal patterns 370b of the first cell region CELL1 and the upper bonding metal patterns 270b of the peripheral circuit region PERI. In some implementations, an operating voltage of the circuit elements 220b constituting the row decoder may be different from an operating voltage of the circuit elements 220c constituting the page buffer. For example, the operating voltage of the circuit elements 220c constituting the page buffer may be greater than the operating voltage of the circuit elements 220b constituting the row decoder.

Likewise, in the word line bonding region WLBA, the word lines 430 of the second cell region CELL2 may extend in the second direction (e.g., the X-axis direction) parallel to the top surface of the third substrate 410 and may be connected to a plurality of cell contact plugs 440 (441 to 447). The cell contact plugs 440 may be connected to the peripheral circuit region PERI through an upper metal pattern of the second cell region CELL2 and lower and upper metal patterns and a cell contact plug 348 of the first cell region CELL1.

In the word line bonding region WLBA, the upper bonding metal patterns 370b may be formed in the first cell region CELL1, and the upper bonding metal patterns 270b may be formed in the peripheral circuit region PERI. The upper bonding metal patterns 370b of the first cell region CELL1 and the upper bonding metal patterns 270b of the peripheral circuit region PERI may be electrically connected to each other by the bonding method. The upper bonding metal patterns 370b and the upper bonding metal patterns 270b may be formed of aluminum, copper, or tungsten.

In the external pad bonding region PA, a lower metal pattern 371e may be formed in a lower portion of the first cell region CELL1, and an upper metal pattern 472a may be formed in an upper portion of the second cell region CELL2. The lower metal pattern 371e of the first cell region CELL1 and the upper metal pattern 472a of the second cell region CELL2 may be connected to each other by the bonding method in the external pad bonding region PA. Likewise, an upper metal pattern 372a may be formed in an upper portion of the first cell region CELL1, and an upper metal pattern 272a may be formed in an upper portion of the peripheral circuit region PERI. The upper metal pattern 372a of the first cell region CELL1 and the upper metal pattern 272a of the peripheral circuit region PERI may be connected to each other by the bonding method.

Common source line contact plugs 380 and 480 may be disposed in the external pad bonding region PA. The common source line contact plugs 380 and 480 may be formed of a conductive material, such as a metal, a metal compound, and/or doped polysilicon. The common source line contact plug 380 of the first cell region CELL1 may be electrically connected to the common source line 320, and the common source line contact plug 480 of the second cell region CELL2 may be electrically connected to the common source line 420. A first metal line 350a and a second metal line 360a may be sequentially stacked on the common source line contact plug 380 of the first cell region CELL1, and a first metal line 450a and a second metal line 460a may be sequentially stacked on the common source line contact plug 480 of the second cell region CELL2.

Input/output pads 205, 405 and 406 may be disposed in the external pad bonding region PA. Referring to FIG. 3c, a lower insulating layer 201 may cover a bottom surface of the first substrate 210, and a first input/output pad 205 may be formed on the lower insulating layer 201. The first input/output pad 205 may be connected to at least one of a plurality of the circuit elements 220a disposed in the peripheral circuit region PERI through a first input/output contact plug 203 and may be separated from the first substrate 210 by the lower insulating layer 201. In addition, a side insulating layer may be disposed between the first input/output contact plug 203 and the first substrate 210 to electrically isolate the first input/output contact plug 203 from the first substrate 210.

An upper insulating layer 401 covering a top surface of the third substrate 410 may be formed on the third substrate 410. A second input/output pad 405 and/or a third input/output pad 406 may be disposed on the upper insulating layer 401. The second input/output pad 405 may be connected to at least one of the circuit elements 220a disposed in the peripheral circuit region PERI through second input/output contact plugs 403 and 303, and the third input/output pad 406 may be connected to at least one of the circuit elements 220a disposed in the peripheral circuit region PERI through third input/output contact plugs 404 and 304.

In some implementations, the third substrate 410 may not be disposed in a region in which the input/output contact plug is disposed. For example, as illustrated in a region ‘B’, the third input/output contact plug 404 may be separated from the third substrate 410 in a direction parallel to the top surface of the third substrate 410 and may penetrate an interlayer insulating layer 415 of the second cell region CELL2 so as to be connected to the third input/output pad 406. In this case, the third input/output contact plug 404 may be formed by at least one of various processes.

In some implementations, as illustrated in a region ‘B1’, the third input/output contact plug 404 may extend in a third direction (e.g., the Z-axis direction), and a diameter of the third input/output contact plug 404 may become progressively greater toward the upper insulating layer 401. In other words, a diameter of the channel structure CH described in the region ‘A1’ may become progressively less toward the upper insulating layer 401, but the diameter of the third input/output contact plug 404 may become progressively greater toward the upper insulating layer 401. For example, the third input/output contact plug 404 may be formed after the second cell region CELL2 and the first cell region CELL1 are bonded to each other by the bonding method.

In some implementations, as illustrated in a region ‘B2’, the third input/output contact plug 404 may extend in the third direction (e.g., the Z-axis direction), and a diameter of the third input/output contact plug 404 may become progressively less toward the upper insulating layer 401. In other words, like the channel structure CH, the diameter of the third input/output contact plug 404 may become progressively less toward the upper insulating layer 401. For example, the third input/output contact plug 404 may be formed together with the cell contact plugs 440 before the second cell region CELL2 and the first cell region CELL1 are bonded to each other.

In some implementations, the input/output contact plug may overlap with the third substrate 410. For example, as illustrated in a region ‘C’, the second input/output contact plug 403 may penetrate the interlayer insulating layer 415 of the second cell region CELL2 in the third direction (e.g., the Z-axis direction) and may be electrically connected to the second input/output pad 405 through the third substrate 410. In this case, a connection structure of the second input/output contact plug 403 and the second input/output pad 405 may be realized by various methods.

In some implementations, as illustrated in a region ‘C1’, an opening 408 may be formed to penetrate the third substrate 410, and the second input/output contact plug 403 may be connected directly to the second input/output pad 405 through the opening 408 formed in the third substrate 410. In this case, as illustrated in the region ‘C1’, a diameter of the second input/output contact plug 403 may become progressively greater toward the second input/output pad 405. However, implementations are not limited thereto, and in some implementations, the diameter of the second input/output contact plug 403 may become progressively less toward the second input/output pad 405.

In some implementations, as illustrated in a region ‘C2’, the opening 408 penetrating the third substrate 410 may be formed, and a contact 407 may be formed in the opening 408. An end of the contact 407 may be connected to the second input/output pad 405, and another end of the contact 407 may be connected to the second input/output contact plug 403. Thus, the second input/output contact plug 403 may be electrically connected to the second input/output pad 405 through the contact 407 in the opening 408. In this case, as illustrated in the region ‘C2’, a diameter of the contact 407 may become progressively greater toward the second input/output pad 405, and a diameter of the second input/output contact plug 403 may become progressively less toward the second input/output pad 405. For example, the second input/output contact plug 403 may be formed together with the cell contact plugs 440 before the second cell region CELL2 and the first cell region CELL1 are bonded to each other, and the contact 407 may be formed after the second cell region CELL2 and the first cell region CELL1 are bonded to each other.

In some implementations illustrated in a region ‘C3’, a stopper 409 may further be formed on a bottom end of the opening 408 of the third substrate 410, as compared with the implementations of the region ‘C2’. The stopper 409 may be a metal line formed in the same layer as the common source line 420. Alternatively, the stopper 409 may be a metal line formed in the same layer as at least one of the word lines 430. The second input/output contact plug 403 may be electrically connected to the second input/output pad 405 through the contact 407 and the stopper 409.

Like the second and third input/output contact plugs 403 and 404 of the second cell region CELL2, a diameter of each of the second and third input/output contact plugs 303 and 304 of the first cell region CELL1 may become progressively less toward the lower metal pattern 371e or may become progressively greater toward the lower metal pattern 371e.

Meanwhile, in some implementations, a slit 411 may be formed in the third substrate 410. For example, the slit 411 may be formed at a certain position of the external pad bonding region PA. For example, as illustrated in a region ‘D’, the slit 411 may be located between the second input/output pad 405 and the cell contact plugs 440 when viewed in a plan view. Alternatively, the second input/output pad 405 may be located between the slit 411 and the cell contact plugs 440 when viewed in a plan view.

In some implementations, as illustrated in a region ‘D1’, the slit 411 may be formed to penetrate the third substrate 410. For example, the slit 411 may be used to prevent the third substrate 410 from being finely cracked when the opening 408 is formed. However, implementations are not limited thereto, and in some implementations, the slit 411 may be formed to have a depth ranging from about 60% to about 70% of a thickness of the third substrate 410.

In some implementations, as illustrated in a region ‘D2’, a conductive material 412 may be formed in the slit 411. For example, the conductive material 412 may be used to discharge a leakage current occurring in driving of the circuit elements in the external pad bonding region PA to the outside. In this case, the conductive material 412 may be connected to an external ground line.

In some implementations, as illustrated in a region ‘D3’, an insulating material 413 may be formed in the slit 411. For example, the insulating material 413 may be used to electrically isolate the second input/output pad 405 and the second input/output contact plug 403 disposed in the external pad bonding region PA from the word line bonding region WLBA. Because the insulating material 413 is formed in the slit 411, it is possible to prevent a voltage provided through the second input/output pad 405 from affecting a metal layer disposed on the third substrate 410 in the word line bonding region WLBA.

Meanwhile, in some implementations, the first to third input/output pads 205, 405 and 406 may be selectively formed. For example, the memory device 500 may be realized to include only the first input/output pad 205 disposed on the first substrate 210, to include only the second input/output pad 405 disposed on the third substrate 410, or to include only the third input/output pad 406 disposed on the upper insulating layer 401.

In some implementations, at least one of the second substrate 310 of the first cell region CELL1 or the third substrate 410 of the second cell region CELL2 may be used as a sacrificial substrate and may be completely or partially removed before or after a bonding process. An additional layer may be stacked after the removal of the substrate. For example, the second substrate 310 of the first cell region CELL1 may be removed before or after the bonding process of the peripheral circuit region PERI and the first cell region CELL1, and then, an insulating layer covering a top surface of the common source line 320 or a conductive layer for connection may be formed. Likewise, the third substrate 410 of the second cell region CELL2 may be removed before or after the bonding process of the first cell region CELL1 and the second cell region CELL2, and then, the upper insulating layer 401 covering a top surface of the common source line 420 or a conductive layer for connection may be formed.

The memory cell array 110 of FIG. 1 may be disposed on the first cell region CELL1 and/or the second cell region CELL2.

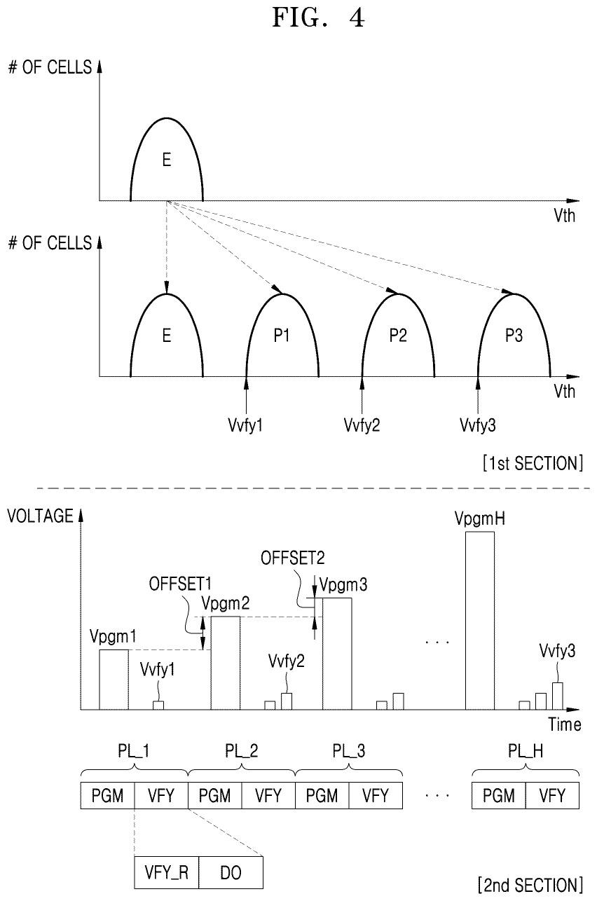

FIG. 4 is a diagram illustrating an example of a program operation for memory cells. FIG. 4 is described with reference to FIG. 2.

In FIG. 4, for convenience of description, a memory cell is assumed to be a multi-level cell, and the description given below may also be applied to a single level cell, a triple level cell, or a quadruple level cell.

Referring to FIG. 4, as shown in a first section, memory cells of a memory cell array may have one of the erase state E and the program states P1 to P3. For example, memory cells may be in an erase state E as an initial state, and as a result of performing programming on the memory cells, the memory cells may be in one of the erase state E and program states P1 to P3.

As shown in a second section, the memory device 100 may program memory cells, based on the ISPP. The memory device 100 may program memory cells by performing a plurality of program loops PL_1 to PL_H. Each of the program loops PL_1 to PL_H may include a program operation PGM of applying program voltages Vpgm1 to VpgmH to a selected word line and a verification operation VFY of verifying a program state of the memory cells. Each time the program loops PL_1 to PL_H are sequentially performed, a program voltage applied to the selected word line in the program operation PGM may increase by an offset voltage OFFSET. For example, a difference between the program voltage Vpgm1 of the first program loop PL_1 and the program voltage Vpgm2 of the second program loop PL_2 may be a first offset voltage OFFSET1, and a difference between the program voltage Vpgm2 of the second program loop PL_2 and the program voltage Vpgm3 of the third program loop PL_3 may be a second offset voltage OFFSET2. The first offset voltage OFFSET1 and the second offset voltage OFFSET2 may be controlled by the memory device 100 to be the same or different.

The verification operation VFY may include a verification read operation VFY_R and a determination operation DO. The verification read operation VFY_R refers to an operation of reading memory cells based on first to third verification voltages Vvfy1 to Vvfy3. For example, memory cells in which a target program state is the program state P1 may be read by the first verification voltage Vvfy1. A memory cell having the target program state as the program state P1 and programmed to the program state P1 is read as an off-cell by the first verification voltage Vvfy1, and a memory cell having the target program state as the program state P1 and not programmed yet to the program state P1 may be read as an on-cell by the first verification voltage Vvfy1. For memory cells having the target program state as the program state P2 or the program state P3, a verification read operation VFY_R may be performed as described above using the second verification voltage Vvfy2 or the third verification voltage Vvfy3.

After the verification read operation VFY_R is performed, the determination operation DO may be performed, and the determination operation DO may include an operation of determining pass/fail for the program operation PGM of the program loop and, furthermore, the determination operation DO may include an operation of determining the tendency of a threshold voltage distribution formed by the memory cells by the program operation PGM and fast cell and slow cell-related characteristics of the memory cells, etc. The determination operation DO may be performed using the number of off-cells generated in the verification read operation VFY_R.

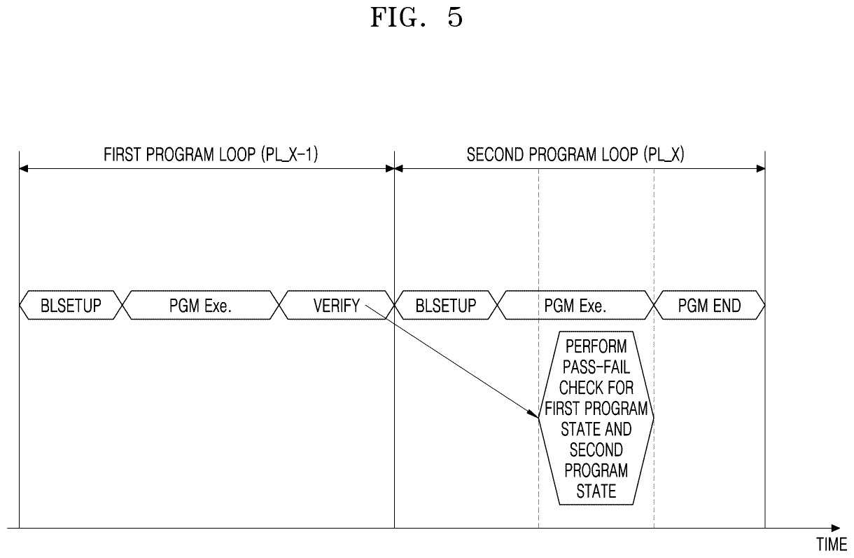

FIG. 5 illustrates an example of a timing of a pass-fail check operation in a program state. FIG. 5 is described with reference to FIG. 2, and redundant descriptions are omitted.

FIG. 5 illustrates an X−1-th program loop PL_X−1 and an X-th program loop PL_X. Hereinafter, in the present disclosure, the X−1-th program loop may be referred to as a first program loop PL_X−1, and the X-th program loop PL_X may be referred to as a second program loop.

Each program loop may include one program voltage and one or more verification voltages, and a program voltage may increase as the program loop progresses. In each program loop, a program operation is performed by a program voltage, and a program verification operation is performed by one or more verification voltages.

In a bit line setup BLSETUP section of each program loop, bit lines are set up. For example, one of a ground voltage 0v, a program prohibition voltage (e.g., power supply voltage (VCC)), and a bit line forcing voltage may be provided to the bit lines connected to cells to be programmed.

When the first program loop PL_X−1 progresses, a first program voltage may be applied to a selected word line in a program voltage application section PGM Exe. In a verification voltage application section Verify of the first program loop PL_X−1, a first verification voltage and a second verification voltage may be applied to the selected word line.

When the second program loop PL_X progresses, a second program voltage may be applied to the selected word line in the program voltage application section PGM Exe. The second program voltage may be used to program memory cells into at least one of a first program state and a second program state.

The memory device 100 may perform a path-fail check of the first program state and the second program state in the program voltage application section PGM Exe of the second program loop PL_X using a result of applying the first verification voltage and a result of applying the second verification voltage in the first program loop PL_X−1. In addition, the memory device 100 may adjust a timing of performing the pass-fail check in the program voltage application section PGM Exe of the second program loop PL_X. Implementations are described below.

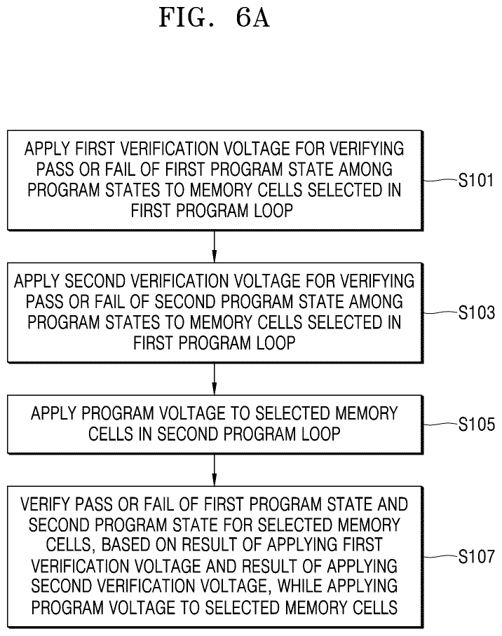

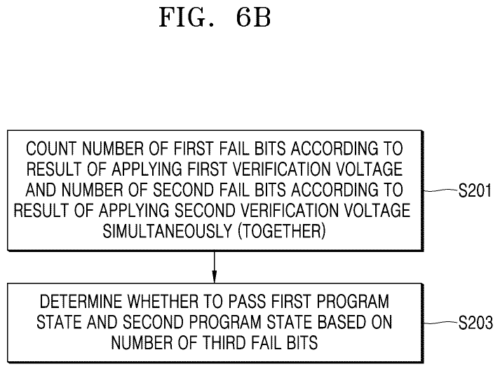

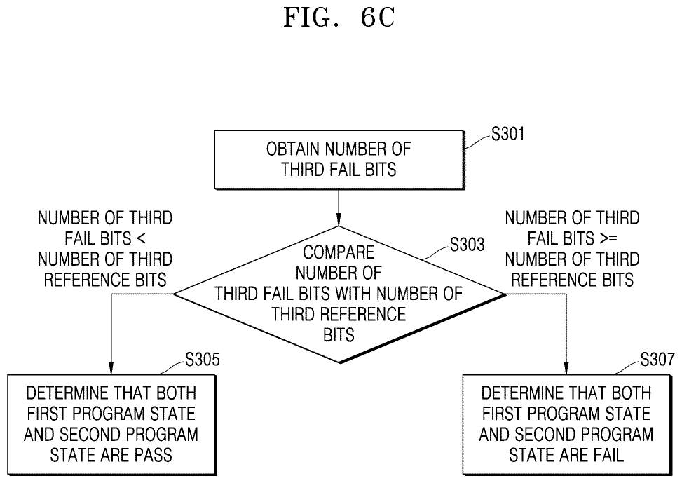

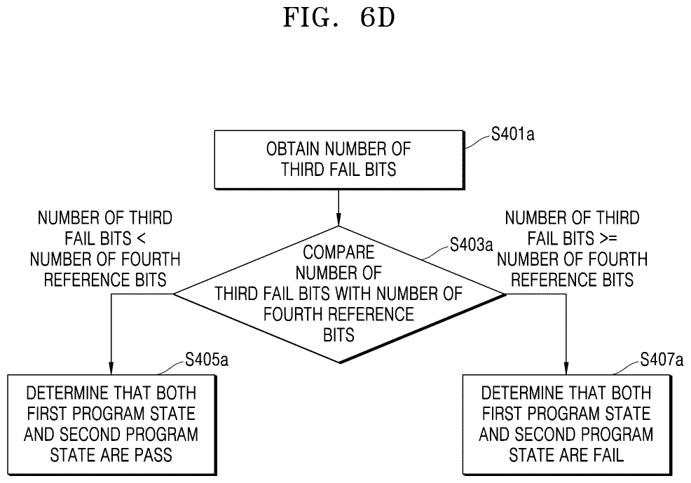

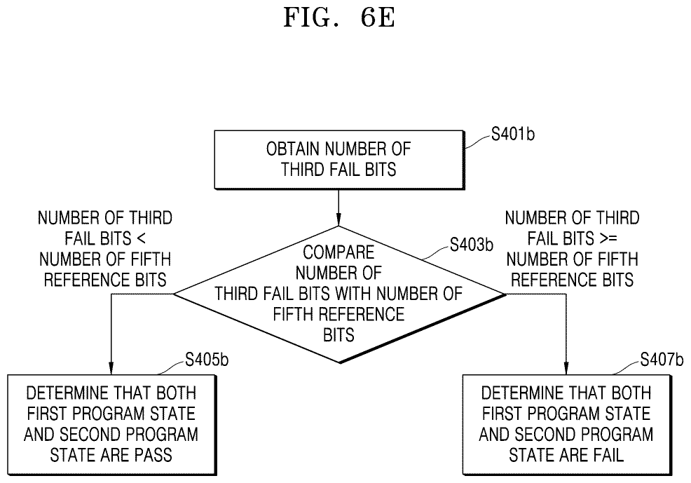

FIG. 6A illustrates a sequential operation of an example of a nonvolatile memory device. FIG. 6A is described with reference to FIGS. 2 and 5, and redundant descriptions are omitted.

Referring to FIG. 6A, in operation S101, the memory device 100 may apply a first verification voltage for verifying pass or fail of the first program state among a plurality of program states to memory cells selected in the first program loop PL_X−1.

In operation S103, the memory device 100 may apply a second verification voltage for verifying pass or fail of the second program state among the program states to the memory cells selected in the first program loop PL_X−1. For example, the first program state may be a program state with the second-highest target threshold voltage, and the second program state may be a program state with the highest target threshold voltage. The first verification and the second verification may have different verification methods. For example, the first verification is based on a multiple-step verification method including 2-step verification, and the second verification is based on 1-step verification.

In operation S105, the memory device 100 may apply a program voltage to the selected memory cells in the second program loop PL_X.

In operation S107, while applying the program voltage to the selected memory cells, the memory device 100 may verify pass or fail of the first program state and the second program state for the selected memory cells, based on a result of applying the first verification voltage and a result of applying the second verification voltage. For example, the memory device 100 may store verification data for applying the first verification voltage in the page buffer circuit 120 and may store data for applying the second verification voltage in the page buffer circuit 120. In addition, the page buffer circuit 120 may transmit a verification signal VFY_S including the data regarding the application of the first verification voltage and the data regarding the application of the second verification voltage in the program voltage application section PGM Exe of the second program loop PL_X to the mass bit counter 130. The mass bit counter 130 may verify pass or fail of the first program state and the second program state, based on the verification signal VFY_S.

Meanwhile, for convenience of description, the pass-fail check for two program states has been described, but the aforementioned method may be to a case of performing a pass-fail check for two or more program states simultaneously and is not limited to the implementation described above. For example, when the memory device 100 simultaneously performs a pass-fail check for three program states, fail bits corresponding to each program state may be counted simultaneously.

FIG. 6B illustrates a sequential operation of an example of a nonvolatile memory device. FIG. 6B is described with reference to FIGS. 2, 5, and 6A, and redundant descriptions are omitted.

Referring to FIG. 6B, in operation S201, the memory device 100 may count the number of first fail bits according to the result of applying the first verification voltage and the number of second fail bits according to the result of applying the second verification voltage simultaneously (together). The first fail bit refers to the number of on-cells that did not reach the target threshold voltage of the first program state. The second fail bit refers to the number of on-cells that did not reach the target threshold voltage of the second program state.

In other words, the memory device 100 may count the number of third fail bits, based on a single count operation, and the third fail bits refer to the number of on-cells that did not reach the target threshold voltage of the first program state and the target threshold voltage of the second program state. That is, the memory device 100 may count the number of third fail bits at once, rather than counting and adding the number of first fail bits and the number of second fail bits. For example, the mass bit counter 130 may count the number of third fail bits, while the second program voltage is applied.

In operation S203, the memory device 100 may determine whether the first program state and the second program state are pass based on the number of third fail bits.

As an example, while the second program voltage is applied to the selected word line, the mass bit counter 130 may determine that both the first program state and the second program state are pass when the number of third fail bits is less than a reference bit.

Meanwhile, for convenience of description, the pass-fail check for two program states has been described, but the aforementioned method may be applied to a case of performing a pass-fail check for two or more program states at the same time and is not limited to the implementation described above. For example, when the memory device 100 simultaneously performs a pass-fail check for three program states, the fail bits corresponding to each program state may be counted together.

FIG. 6C illustrates a sequential operation of an example of a nonvolatile memory device. FIG. 6C is described with reference to FIGS. 2, 5, 6A, and 6B, and redundant descriptions are omitted.

Referring to FIG. 6C, in operation S301, the memory device 100 may obtain the number of third fail bits. In detail, as described above with reference to FIG. 6B, the memory device 100 may count the number of third fail bits.

In operation S303, the memory device 100 may compare the number of third fail bits with the number of third reference bits.

The number of first reference bits refers to the number of fail bits that serve as a reference for the first program state to be pass. The number of second reference bits refers to the number of fail bits that serve as a reference for the second program state to be pass. The third reference bit refers to the sum of the first and second reference bits.

If the number of third fail bits is less than the number of third reference bits, in operation S305, the memory device 100 may determine that both the first program state and the second program state are pass. For example, while the second program voltage is applied to the selected word line, if the number of third fail bits is less than the third reference bit, the mass bit counter 130 may determine that both the first program state and the second program state are pass. The mass bit counter 130 may transmit a signal including information that both the first program state and the second program state are pass to the control logic 160. In addition, if the second program state is the highest program state, the program may be terminated.

If the number of third fail bits is greater than or equal to the number of third reference bits, in operation S307, the memory device 100 may determine that both the first program state and the second program state are fail. For example, while the second program voltage is applied to the selected word line, if the number of third fail bits is greater than or equal to the third reference bit, the mass bit counter 130 may determine that both the first program state and the second program state are fail. The mass bit counter 130 may transmit a signal including information that both the first program state and the second program state are fail to the control logic 160. In this case, the third program loop may proceed after the second program loop PL_X.

FIG. 6D illustrates a sequential operation of an example of a nonvolatile memory device. FIG. 6D is described with reference to FIGS. 2, 5, 6A, and 6B, and redundant descriptions are omitted.

Referring to FIG. 6D, in operation S401a, the memory device 100 may obtain the number of third fail bits.

In operation S403a, the memory device 100 may compare the number of third fail bits with the number of fourth reference bits.

The number of first reference bits refers to the number of fail bits that serve as a reference for the first program state to be pass. The number of second reference bits refers to the number of fail bits that serve as a reference for the second program state to be pass. The third reference bit refers to the sum of the first and second reference bits. The fourth reference bit refers to a value less than the third reference bit. The number of fail bits and the number of reference bits may be expressed as the amount of current.

If the number of third fail bits is less than the number of fourth reference bits, in operation S405a, the memory device 100 may determine that both the first program state and the second program state are pass. For example, while the second program voltage is applied to the selected word line, if the number of third fail bits is less than the fourth reference bit, the mass bit counter 130 may determine that both the first program state and the second program state are pass. The mass bit counter 130 may transmit a signal including information that both the first program state and the second program state are pass to the control logic 160. In addition, if the second program state is the highest program state, the program may be terminated.

If the number of third fail bits is greater than or equal to the number of fourth reference bits, in operation S407a, the memory device 100 may determine that both the first program state and the second program state are fail. For example, while the second program voltage is applied to the selected word line, if the number of third fail bits is greater than or equal to the fourth reference bits, the mass bit counter 130 may determine that both the first program state and the second program state are fail. The mass bit counter 130 may transmit a signal including information that both the first program state and the second program state are fail to the control logic 160. In this case, the third program loop may proceed after the second program loop PL_X.

FIG. 6E illustrates a sequential operation of an example of a nonvolatile memory device. FIG. 6E is described with reference to FIGS. 2, 5, 6A, and 6B, and redundant descriptions are omitted.

Referring to FIG. 6E, in operation S401b, the memory device 100 may obtain the number of third fail bits.

In operation S403b, the memory device 100 may compare the number of third fail bits with the number of fifth reference bits. The fifth reference bit refers to a value greater than the third reference bit.

If the number of third fail bits is less than the number of fifth reference bits, in operation S405b, the memory device 100 may determine that both the first program state and the second program state are pass. For example, while the second program voltage is applied to the selected word line, if the number of third fail bits is less than the fifth reference bits, the mass bit counter 130 may determine that both the first program state and the second program state are pass. The mass bit counter 130 may transmit a signal including information that both the first program state and the second program state are pass to the control logic 160.

If the number of third fail bits is greater than or equal to the number of fifth reference bits, in operation S407b, the memory device 100 may determine that both the first program state and the second program state are fail. For example, while the second program voltage is applied to the selected word line, if the number of third fail bits is greater than or equal to the fifth reference bits, the mass bit counter 130 may determine that both the first program state and the second program state are fail. The mass bit counter 130 may transmit a signal including information that both the first program state and the second program state are fail to the control logic 160.

Meanwhile, in some implementations, regarding a timing of the pass-fail check, the memory device 100 may start the pass-fail check at a timing at which the first fail bit is equal to or less than the sixth reference bit greater than the first reference bit within the program voltage application section PGM Exe of the second program loop PL_X.

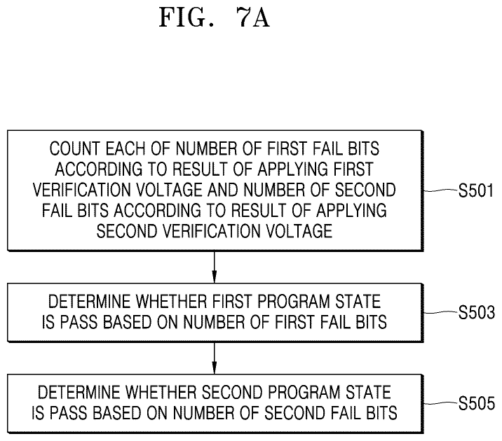

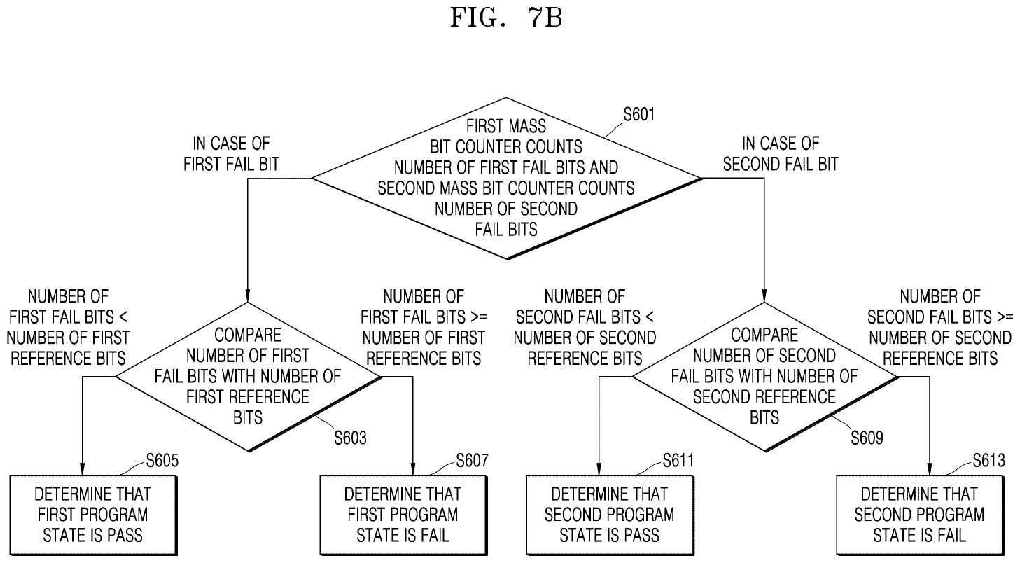

FIG. 7A illustrates a sequential operation of an example of a nonvolatile memory device. FIG. 7A is described with reference to FIGS. 2 and 5, and redundant descriptions are omitted.

Referring to FIG. 7A, in operation S501, the memory device 100 may count each of the number of first fail bits according to a result of applying the first verification voltage and the number of second fail bits according to a result of applying the second verification voltage.

In operation S503, the memory device 100 may determine whether the first program state is pass based on the number of first fail bits.

In operation S505, the memory device 100 may determine the second program state is pass based on the number of second fail bits.

In detail, during the program voltage section PGM Exe of the second program loop PL_X, the memory device 100 may determine whether the first program state is pass based on the number of first fail bits and determine whether the second program state is pass based on the number of second fail bits. That is, the memory device 100 may perform a pass-fail check for each of the first program state and the second program state during the program voltage section PGM Exe of the second program loop PL_X. The order of determining whether the first program state is pass and determining whether the second program state is pass is not limited to the implementation described above, and determining whether the second program state is pass may be performed first.

FIG. 7B illustrates a sequential operation of an example of a nonvolatile memory device. FIG. 7B is described with reference to FIGS. 2, 5, and 7A.

In the memory device 100, by selecting a different page buffer block for each program state, the first mass bit counter 131 may perform a pass-fail check for the first program state and the second mass bit counter 132 may perform a pass-fail check for the second program state.

In detail, referring to FIG. 7B, in operation S601, the first mass bit counter 131 may count the number of first fail bits, and the second mass bit counter 132 may count the number of second fail bits.

In the case of the first fail bit, in operation S603, the first mass bit counter 131 may compare the number of first fail bits with the number of first reference bits.

In operation S605, if the number of first fail bits is less than the number of first reference bits, the first mass bit counter 131 may determine that the first program state is pass. In addition, the first mass bit counter 131 may transmit a pass signal including information that the first program state is pass to the control logic 160.

In operation S607, if the number of first fail bits is greater than or equal to the number of first reference bits, the first mass bit counter 131 may determine that the first program state is fail. In addition, the first mass bit counter 131 may transmit a fail signal including information that the first program state is fail to the control logic 160.

In the case of the second fail bit, in operation S609, the second mass bit counter 132 may compare the number of second fail bits with the number of second reference bits.

In operation S611, if the number of second fail bits is less than the number of second reference bits, the second mass bit counter 132 may determine that the second program state is pass. In addition, the second mass bit counter 132 may transmit a pass signal including information that the second program state is pass to the control logic 160.

In operation S613, if the number of second fail bits is greater than or equal to the number of second reference bits, the second mass bit counter 132 may determine that the second program state is fail. In addition, the second mass bit counter 132 may transmit a fail signal including information that the second program state is fail to the control logic 160.

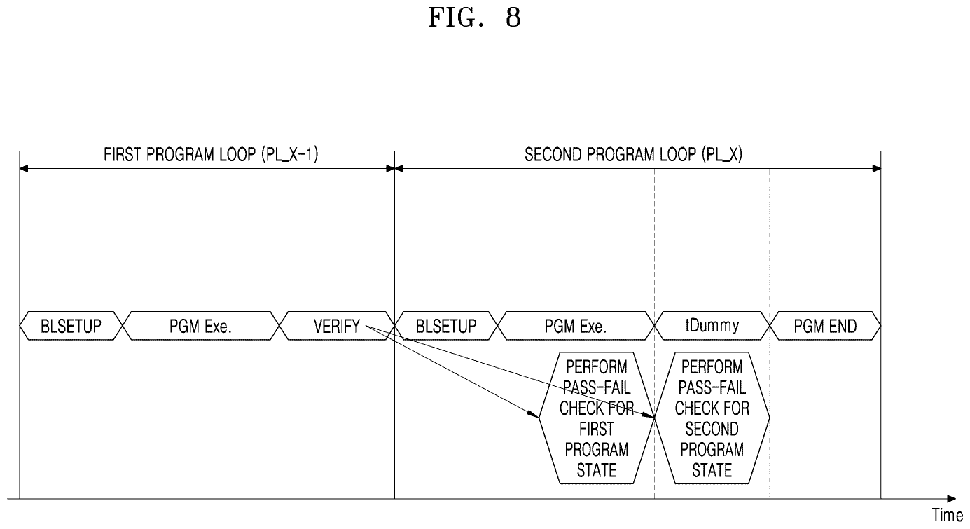

FIG. 8 illustrates an example of a timing of a pass-fail check operation of a program state. FIG. 8 is described with reference to FIGS. 2 and 5, and redundant descriptions are omitted.

Referring to FIG. 8, when the second program loop PL_X progresses, the program voltage may be applied to a selected word line in the program voltage application section PGM Exe. The program voltage may be used to program memory cells to the first program state and the second program state.

The memory device 100 may perform a pass-fail check of the first program state in the program voltage application section PGM Exe of the second program loop PL_X using the result of applying the verification voltage in the verification voltage application section Verify of the first program loop PL_X−1, and may continuously perform a pass-fail check of the second program state.

For example, the pass-fail check for the second program state may be performed in a dummy section tDummy after the program voltage application section PGM Exe. Meanwhile, if the pass-fail check for the first program state is completed early, the pass-fail check for the second program state may be performed in the program voltage application section PGM Exe.

In addition, as described above, when the memory device 100 performs the pass-fail check of the first program state and continuously performs the pass-fail check of the second program state, the pass-fail check may be performed, starting from the highest program state. That is, a threshold voltage for the first program state may be higher than a threshold voltage for the second program state.

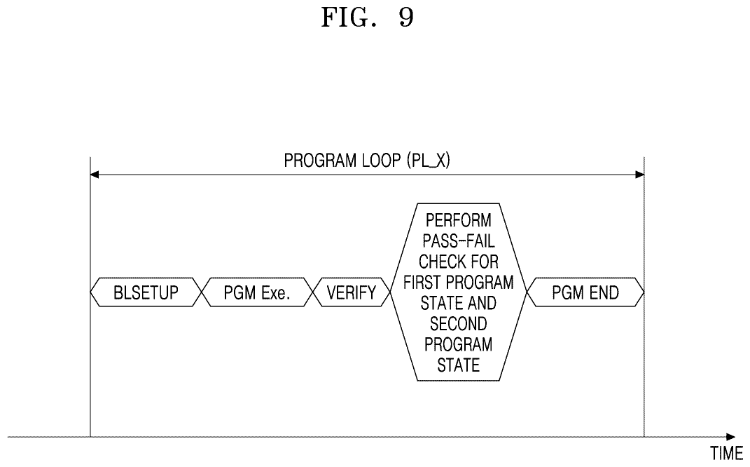

FIG. 9 illustrates an example of a timing of a pass-fail check operation of a program state. FIG. 9 is described with reference to FIGS. 2 and 5, and redundant descriptions are omitted.

FIG. 9 illustrates the program loop PL_X. The program loop PL_X may include one program voltage and one or more verification voltages, and the program voltage may increase as the program loop progresses. In each program loop, a program operation may be performed using a program voltage, and a program verification operation may be performed using one or more verification voltages.

When the program loop PL_X progresses, the program voltage may be applied to a selected word line in the program voltage application section PGM Exe. The program voltage may be used to program memory cells to the first program state and the second program state.

Verification voltages may be applied to the selected word line in the verification section Verify of the program loop PL_X. The memory device 100 may perform a pass-fail check of the first program state and the second program state in the program voltage application section PGM Exe of the program loop PL_X using the results of applying the verification voltages. Implementations are described below.

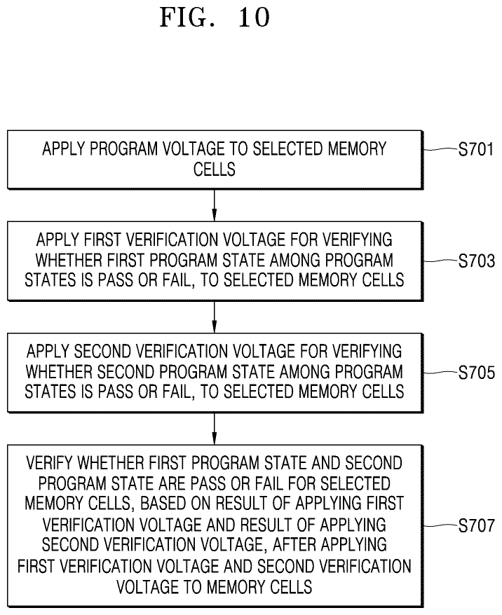

FIG. 10 illustrates an example of a method of operating a memory device. FIG. 10 is described with reference to FIGS. 2 and 10.

Referring to FIG. 10, in operation S701, the memory device 100 may apply a program voltage to selected memory cells.

In operation S703, the memory device 100 may apply a first verification voltage for verifying whether the first program state among the program states is pass or fail to the selected memory cells.

In operation S705, the memory device 100 may apply a second verification voltage for verifying whether the second program state among the program states is pass or fail to the selected memory cells.

In operation S707, the memory device 100 may verify whether the first program state and the second program state are pass or fail for the selected memory cells, based on a result of applying the first verification voltage and a result of applying the second verification voltage, after applying the first verification voltage and the second verification voltage to the memory cells. The memory device 100 only differs in the timing of the pass-fail check from the implementations described above with reference to FIGS. 6A to 6D, 7A, and 7B, and may verify whether the first program state and the second program state are pass or fail by applying the method described above.

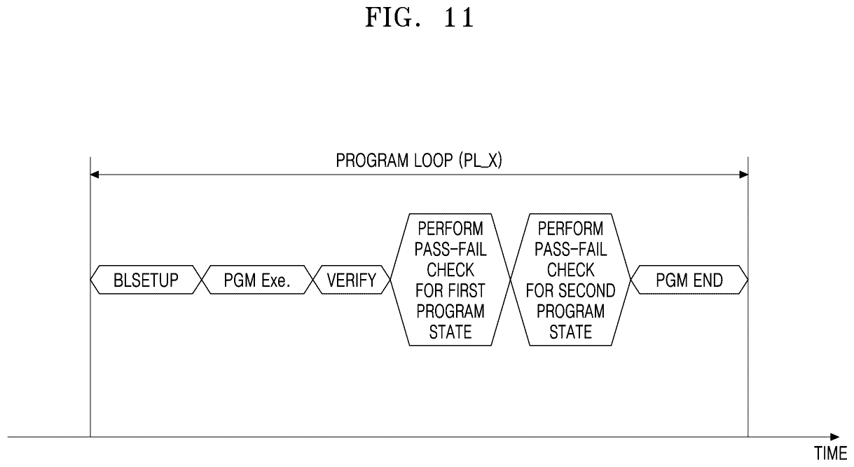

FIG. 11 illustrates an example of a timing of a pass-fail check operation of a program state. FIG. 11 is described with reference to FIGS. 2, 5, and 10.

Referring to FIG. 11, when the program loop PL_X progresses, a program voltage may be applied to a selected word line in the program voltage application section PGM Exe. The program voltage may be used to program memory cells to the first program state and the second program state. Verification voltages may be applied to the selected word line in the verification voltage application section Verify of the program loop PL_X. For example, in the verification voltage application period Verify, the first verification voltage and the second verification voltage may be applied to the selected word line.

The memory device 100 may perform a pass-fail check of the first program state in the program voltage application section PGM Exe and continuously perform a pass-fail check of the second program state using results of applying the first verification voltage and applying the second verification voltage.

In addition, as described above, when the memory device 100 performs a pass-fail check of the first program state and continuously performs a pass-fail check of the second program state, the pass-fail check may be performed, starting from the highest program state. That is, a threshold voltage for the first program state may be higher than a threshold voltage for the second program state.

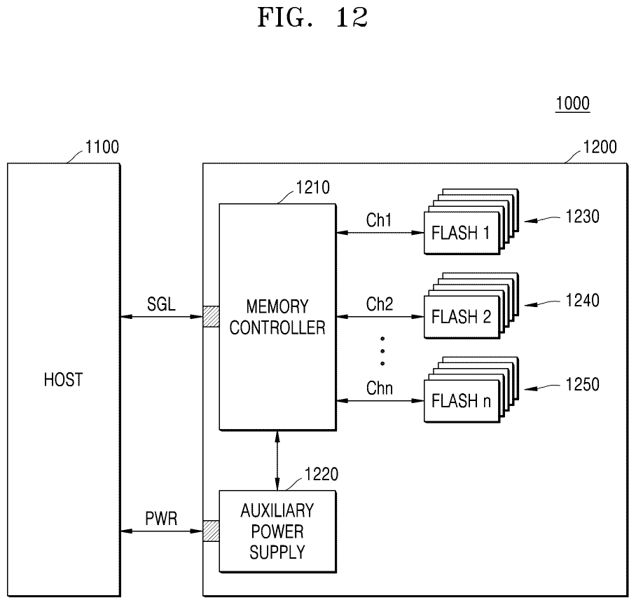

FIG. 12 is a block diagram illustrating an example of a solid state drive (SSD) system 1000.

Referring to FIG. 12, the SSD system 1000 may include a host 1100 and an SSD 1200. The SSD 1200 may exchange signals SGL with the host 1100 through a signal connector and receive power PWR through a power connector. The SSD 1200 may include a memory controller 1210, an auxiliary power supply 1220, and a plurality of memory devices 1230, 1240, and 1250.

The memory devices 1230, 1240, and 1250 may be connected to the memory controller 1210 through channels Ch1 to Chn to perform a mass bit count operation according to implementations. In detail, the memory devices 1230, 1240, and 1250 may perform a pass-fail check on program states according to the implementations described above.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been particularly shown and described with reference to implementations thereof, it will be understood that various changes in form and details may be made therein without departing from the spirit and scope of the following claims.

What is claimed is:

1. An operating method of a nonvolatile memory device, the operating method comprising:
applying a first verification voltage to a plurality of selected memory cells in a first program loop that verifies pass or fail of a first program state among a plurality of program states;
applying a second verification voltage to the plurality of selected memory cells in the first program loop that verifies pass or fail of a second program state among the plurality of program states;
applying a program voltage to the plurality of selected memory cells in a second program loop; and
based on the program voltage being applied to the plurality of selected memory cells, verifying pass or fail of the first program state and the second program state for the plurality of selected memory cells based on a result of applying the first verification voltage and a result of applying the second verification voltage.

2. The operating method of claim 1, wherein a method of applying the first verification voltage is different from a method of applying the second verification voltage.

3. The operating method of claim 1, wherein when the plurality of selected memory cells are a plurality of quadruple level cells, the plurality of program states include an erase state and 15 program states, and the first program state and the second program state are adjacent to each other among the 15 program states.

4. The operating method of claim 1, wherein when the plurality of selected memory cells are a plurality of triple level cells, the plurality of program states include an erase state and seven program states, and the first program state and the second program state are adjacent to each other among the seven program states.

5. The operating method of claim 1, wherein verifying pass or fail of the first program state and the second program state includes:
counting a number of first fail bits as the result of applying the first verification voltage and counting a number of second fail bits as the result of applying the second verification voltage; and
determining whether the first program state and the second program state pass based on a number of third fail bits, the number of third fail bits being a sum of the number of first fail bits and the number of second fail bits.

6. The operating method of claim 5, wherein determining whether the first program state and the second program state pass based on the number of third fail bits includes:
comparing the number of third fail bits and a number of fourth reference bits; and
when the number of third fail bits is less than the number of fourth reference bits, determining that both the first program state and the second program state pass,
wherein the number of fourth reference bits is a value less than a number of third reference bits, the number of third reference bits being a sum of a number of first reference bits for the first program state and a number of second reference bits for the second program state.

7. The operating method of claim 6, wherein determining whether the first program state and the second program state pass based on the number of third fail bits includes:
determining that both the first program state and the second program state fail when the number of third fail bits is greater than or equal to the number of fourth reference bits.

8. The operating method of claim 5, wherein determining whether the first program state and the second program state pass based on the number of third fail bits includes:
comparing the number of third fail bits and a number of fifth reference bits; and
when the number of third fail bits is less than the number of fifth reference bits, determining that both the first program state and the second program state pass,
wherein the number of fifth reference bits is a value greater than a number of third reference bits, the number of third reference bits being a sum of a number of first reference bits for the first program state and a number of second reference bits for the second program state.

9. The operating method of claim 8, wherein determining whether the first program state and the second program state pass based on the number of third fail bits includes:
determining that both the first program state and the second program state fail when the number of third fail bits is greater than or equal to the number of fifth reference bits.

10. The operating method of claim 5, wherein determining whether the first program state and the second program state pass based on the number of third fail bits includes:
comparing the number of third fail bits and a number of third reference bits; and
determining that both the first program state and the second program state pass when the number of third fail bits is less than the number of third reference bits,
wherein the number of third reference bits is a sum of a number of first reference bits for the first program state and a number of second reference bits for the second program state.

11. The operating method of claim 1, wherein verifying pass or fail of the first program state and the second program state includes:
counting a number of first fail bits as the result of applying the first verification voltage and counting a number of second fail bits as the result of applying the second verification voltage;
determining whether the first program state passes based on the number of first fail bits; and
determining whether the second program state passes based on the number of second fail bits.

12. The operating method of claim 1, wherein verifying pass or fail of the first program state and the second program state includes:
counting, by a first mass bit counter connected to a first page buffer block, a number of first fail bits according to the result of applying the first verification voltage;
comparing the number of first fail bits and a number of first reference bits for the first program state;
determining, by the first mass bit counter, that the first program state passes when the number of first fail bits is less than the number of first reference bits;
counting, by a second mass bit counter connected to a second page buffer block, a number of second fail bits according to the result of applying the second verification voltage;
comparing the number of second fail bits and a number of second reference bits for the second program state; and
determining, by the second mass bit counter, that the second program state passes when the number of second fail bits is less than the number of second reference bits.

13. A nonvolatile memory device comprising:
a memory cell array including a plurality of memory cells;
a page buffer circuit including a plurality of page buffer blocks, the plurality of page buffer blocks connected to the memory cell array through a plurality of bit lines;
a control logic configured to
apply a first verification voltage to a plurality of selected memory cells among the plurality of memory cells in a first program loop that verifies pass or fail of a first program state among a plurality of program states,
apply a second verification voltage to the plurality of selected memory cells in the first program loop that verifies pass or fail of a second program state among the plurality of program state, and
apply a program voltage to the plurality of selected memory cells in a second program loop; and
a mass bit counter configured to verify, based on the program voltage being applied to the plurality of selected memory cells, pass or fail of the first program state and the second program state for the plurality of selected memory cells based on a result of applying the first verification voltage and a result of applying the second verification voltage.

14. The nonvolatile memory device of claim 13, wherein a method of applying the first verification voltage is different from a method of applying the second verification voltage.

15. The nonvolatile memory device of claim 13, wherein when the plurality of selected memory cells are a plurality of quadruple level cells, the plurality of program states include an erase state and 15 program states, and the first program state and the second program state are adjacent to each other among the 15 program states.

16. The nonvolatile memory device of claim 13, wherein the mass bit counter is configured to:
count a number of first fail bits according to the result of applying the first verification voltage and count a number of second fail bits according to the result of applying the second verification voltage, and
determine whether the first program state and the second program state pass based on a number of third fail bits, the number of third fail bits being a sum of the number of the first fail bits and the number of the second fail bits.

17. The nonvolatile memory device of claim 16, wherein the mass bit counter is configured to:
compare the number of third fail bits and a number of fourth reference bits, and
determine that both the first program state and the second program state pass when the number of the third fail bits is less than the number of the fourth reference bits,
wherein the number of fourth reference bits is a value that is less than a number of third reference bits, the number of third reference bits being a sum of a number of first reference bits for the first program state and a number of second reference bits for the second program state.

18. The nonvolatile memory device of claim 17, wherein the mass bit counter is configured to determine that both the first program state and the second program state fail when the number of third fail bits is greater than or equal to the number of the fourth reference bits.

19. The nonvolatile memory device of claim 13, wherein
the mass bit counter includes a first mass bit counter and a second mass bit counter,
the plurality of page buffer blocks include a first page buffer block and a second page buffer block,
the first mass bit counter is connected to the first page buffer block and is configured to
count a number of first fail bits according to the result of applying the first verification voltage,
compare the number of first fail bits and a number of first reference bits for the first program state, and
determine that the first program state passes when the number of first fail bits is less than the number of first reference bits, and
the second mass bit counter is connected to the second page buffer block and is configured to
count a number of second fail bits according to the result of applying the second verification voltage,
compare the number of second fail bits and a number of second reference bits for the second program state, and
determine that the second program state passes when the number of second fail bits is less than the number of second reference bits.

20. An operating method of a nonvolatile memory device, the operating method comprising:
applying a program voltage to a plurality of selected memory cells;
applying a first verification voltage to the plurality of selected memory cells that verifies pass or fail of a first program state among a plurality of program states;
applying a second verification voltage to the plurality of selected memory cells that verifies pass or fail of a second program state among the plurality of program states; and
after applying the first verification voltage and the second verification voltage to the plurality of selected memory cells, verifying pass or fail of the first program state and the second program state for the plurality of selected memory cells based on a result of applying the first verification voltage and a result of applying the second verification voltage.
